(19) United States
(12) Patent Application Publication
(10) Pub. No.: US 2025/0191888 A1
(43) Pub. Date: Jun. 12, 2025

(54) PLASMA PROCESSING DEVICE

(71) Applicant: Tokyo Electron Limited, Tokyo (JP)

(72) Inventors: Masaki HIRAYAMA, Tokyo (JP); Takaaki KATO, Yamanashi (JP)

(21) Appl. No.: 19/060,520

(22) Filed: Feb. 21, 2025

Related U.S. Application Data
(63) Continuation of application No. PCT/JP2023/030879, filed on Aug. 28, 2023.

(30) Foreign Application Priority Data
Sep. 9, 2022 (JP) 2022-144117

(51) Int. Cl. H01J 37/32; H01L 21/02

(52) U.S. Cl. CPC H01J 37/3244; H01J 37/32541; H01J 37/32568; H01J 37/32082; H01J 2237/3323; H01L 21/0228

(57) ABSTRACT

There is a plasma processing apparatus comprising: a processing chamber that has a stage on which a substrate is placed; a first electrode to which high-frequency power for plasma generation is supplied; a second electrode that faces the first electrode and is configured to form a plasma generation space between the first electrode and the second electrode; and a radiation part that is formed of a dielectric and is configured to radiate the high-frequency power into the plasma generation space from a waveguide formed along an outer periphery of the first electrode, wherein the second electrode is configured to form a processing space between the stage and the second electrode, and has a structure causing a first processing gas to flow in a direction opposite to a direction from the plasma generation space toward the processing space, to supply the first processing gas to the plasma generation space.

### CROSS-REFERENCE TO RELATED APPLICATIONS

This application is a bypass continuation application of International Application No. PCT/JP2023/030879 having an international filing date of Aug. 28, 2023 and designating the United States, the International Application being based upon and claiming the benefit of priority from Japanese Patent Application No. 2022-144117 filed on Sep. 9, 2022, the entire contents of which are incorporated herein by reference.

### TECHNICAL FIELD

The present disclosure relates to a plasma processing apparatus.

### BACKGROUND

For example, Japanese Laid-open Patent Publication No. 2014-532988 proposes an etching chamber having a plurality of chamber regions for alternately generating different plasmas. In Japanese Laid-open Patent Publication No. 2014-532988, a first charge-coupled plasma source is provided for generating an ion flux to the wafer in one mode of operation, while a second plasma source is provided for providing a reactive species flux to the wafer without significant ion flux in another mode of operation. A controller is operated to repeatedly cycle the operating modes over time to remove a desired accumulated amount of dielectric material.

### SUMMARY

The present disclosure provides a technology capable of achieving uniformity of substrate processing.

In accordance with an exemplary embodiment of the present disclosure, there is a plasma processing apparatus comprising: a processing chamber that has a stage on which a substrate is placed; a first electrode to which high-frequency power for plasma generation is supplied; a second electrode that faces the first electrode and is configured to form a plasma generation space between the first electrode and the second electrode; and a radiation part that is formed of a dielectric and is configured to radiate the high-frequency power into the plasma generation space from a waveguide formed along an outer periphery of the first electrode, wherein the second electrode is configured to form a processing space between the stage and the second electrode, and has a structure causing a first processing gas to flow in a direction opposite to a direction from the plasma generation space toward the processing space, to supply the first processing gas to the plasma generation space.

### BRIEF DESCRIPTION OF THE DRAWINGS

FIG. 1 is a cross-sectional schematic diagram showing an example of a plasma processing apparatus according to a first embodiment.

FIG. 2 is a cross-sectional schematic diagram showing an example of a plasma processing apparatus according to the first embodiment.

FIG. 3 is a cross-sectional view taken along line III-III of FIG. 2.

FIG. 4 illustrates an example of a film forming method using ALD according to one embodiment.

FIG. 5 illustrates an example of a gas used in the film forming method of FIG. 4.

FIG. 6 is a cross-sectional schematic diagram showing an example of a plasma processing apparatus according to a second embodiment.

FIG. 7 is a cross-sectional view taken along line VII-VII of FIG. 6.

FIG. 8 illustrates a modified example of a heat pipe of a plasma processing apparatus according to the second embodiment.

### DETAILED DESCRIPTION

In what follows, embodiments of the present disclosure will be described with reference to appended drawings. The same constituting elements in the respective drawings are given the same reference number, and repeated descriptions thereof will be omitted.

In the present disclosure, deviations in directions such as parallel, right angles, orthogonal, horizontal, vertical, up and down, or left and right are allowed to the extent that does not reduce the effects of the embodiment. The shape of the corner is not limited to right angles and may be rounded into an arch shape. Geometric relationships such as parallel, right angles, orthogonal, horizontal, vertical, circle, and coincident may include approximately parallel, approximately right angles, approximately orthogonal, approximately horizontal, approximately vertical, approximately circle, and approximately coincident.

For example, in film forming using an Atomic Layer Deposition (ALD) device or etching using an Atomic Layer Etching (ALE) device, gas substitution is repeatedly controlled in a short period of time. Therefore, it is important to make the processing space small to realize high-speed gas substitution. On the other hand, in an ALD device, an ALE device, a Chemical Vapor Deposition (CVD) device, and other film forming devices or etching devices, the uniformity of substrate processing deteriorates due to variation in the supply of processing gas into the processing space. For example, in gas supply using a showerhead structure, the pattern of a plurality of gas holes provided in the showerhead affects the thickness of the film formed on the substrate or the etching depth. For example, in a film formed on a substrate, the film corresponding to the area immediately below the gas holes becomes thicker than the film in the other areas, and the pattern of a plurality of gas holes is reflected in the substrate processing (in what follows, the phenomenon above is called pattern transfer), which leads to a factor causing unevenness in substrate processing. If the spacing between processing spaces is reduced, the pattern of a plurality of gas holes may be transferred to the film more easily, and non-uniformity in substrate processing may be more likely to occur. Therefore, a plasma processing apparatus according to one embodiment of the present disclosure proposes a plasma processing apparatus capable of ensuring uniformity in substrate processing even when the spacing between processing spaces is reduced.

### First Embodiment

### Plasma Processing Apparatus

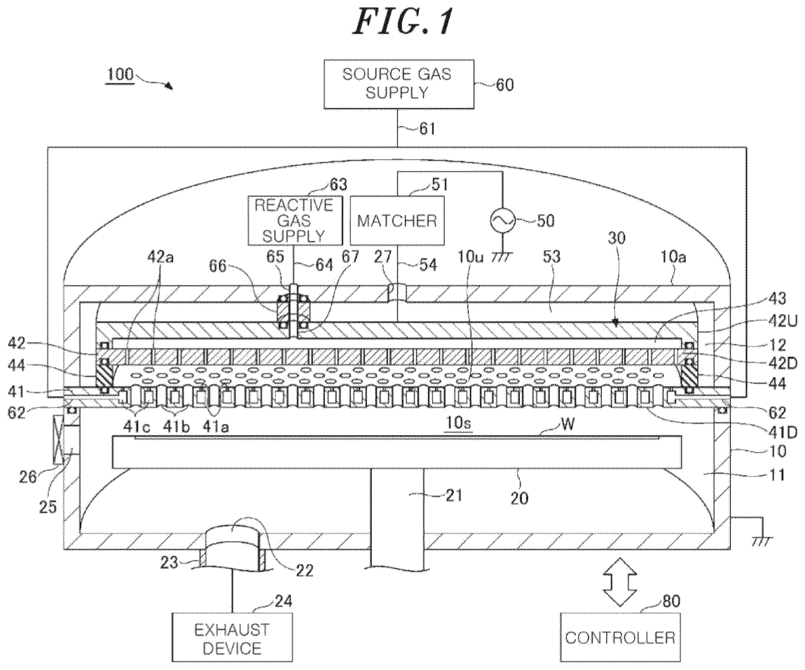

The configuration of the plasma processing apparatus 100 according to a first embodiment will be described with reference to FIG. 1. FIG. 1 is a cross-sectional schematic drawing illustrating one example of the plasma processing apparatus 100 according to the first embodiment. The plasma processing apparatus 100 includes a processing chamber 10, a stage 20 disposed within the processing chamber 10, and a showerhead 30 positioned above the stage 20.

The processing chamber 10 forms an internal space. The substrate W, exemplified by a semiconductor wafer, is processed within the internal space of the processing chamber 10. The processing chamber 10 has an approximately cylindrical shape, with the showerhead 30 positioned at the upper part of the chamber. The processing chamber 10 is made of a metal such as aluminum. The processing chamber 10 is grounded.

The sidewall of the processing chamber 10 provides a passage 25. The substrate W passes through the passage 25 when being transferred between the interior and exterior of the processing chamber 10. The passage 25 may be opened and closed by a gate valve 26. The gate valve 26 is provided along the sidewall of the processing chamber 10.

The bottom of the processing chamber 10 provides an exhaust port 22. The exhaust port 22 is connected to an exhaust device 24 through an exhaust pipe 23. The exhaust device 24 includes a pressure controller with an automatic pressure control valve (not shown) and a vacuum pump such as a turbo molecular pump. The gas inside the processing chamber 10 may be exhausted to the outside by the exhaust device 24 through the exhaust port 22. The processing of the substrate W is carried out by controlling the interior of the processing chamber 10 to maintain a vacuum environment.

The stage 20 is configured to support the substrate W. The substrate W is placed on the stage 20 in an approximately horizontal state. The stage 20 may be supported by a support member 21. The support member 21 extends upward from the bottom of the processing chamber 10. The stage 20 and the support member 21 may be formed of a dielectric material such as aluminum nitride.

Above the stage 20 where the substrate W is placed, an upper electrode 42 and a lower electrode 41 are provided facing each other. The upper electrode 42 and the lower electrode 41 are made of metals such as aluminum alloy, nickel, nickel alloy, or stainless steel.

The showerhead 30 includes the upper electrode 42 and the lower electrode 41. The upper electrode 42 and the lower electrode 41 have a shower plate structure made of metal; the upper electrode 42 comprises an upper shower plate 42D and a support plate 42U, while the lower electrode 41 includes a lower shower plate 41D.

The upper shower plate 42D and the support plate 42U have a disk shape with the same diameter, and the support plate 42U is disposed above the upper shower plate 42D. The lower surface of the support plate 42U protrudes from the periphery toward its circumference, coming into contact with the upper shower plate 42D. The internal space of the support plate 42U faces the upper surface of the upper shower plate 42D and functions as a gas diffusion chamber 43.

High-frequency power in the VHF range is supplied to the upper electrode 42 from the high-frequency power source 50 via the matcher 51 and the power transmission line 54. The high-frequency power in the VHF range is also referred to as VHF power. The upper electrode 42 serves as an example of a first electrode to which high-frequency power for plasma generation is supplied. In the plasma generation space 10u between the upper electrode 42 and the lower electrode 41, VHF power is supplied, and a gas described later is supplied. The plasma processing apparatus 100 is a remote-type plasma processing apparatus that generates plasma from the supplied gas in the plasma generation space 10u and supplies reactive species in the plasma, such as radicals and ions, from the plasma generation space 10u to the processing space 10s.

The power transmission line 54 passes through a through-hole 27 formed in the ceiling wall 10a of the processing chamber 10 and is connected to the upper electrode 42. In the present embodiment, the frequency of the high-frequency power supplied from the high-frequency power source 50 is within the VHF range, specifically 30 MHz to 300 MHz. However, the frequency of the high-frequency power supplied from the high-frequency power source 50 is not limited to the specific range and may, for example, be 13 MHz or higher within the RF range or fall within the UHF range. The frequency of UHF waves ranges from 300 MHz to 3 GHz.

The lower electrode 41 opposes the upper electrode 42 and serves as an example of a second electrode configured to form the plasma generation space 10u between the lower electrode 41 and the upper electrode 42. The lower shower plate 41D is positioned below and faces the upper shower plate 42D. The lower shower plate 41D has a disk shape with a diameter larger than that of the upper shower plate 42D and equal to the diameter of the processing chamber 10. The periphery of the lower shower plate 41D is secured between the sidewalls of the processing chamber 10, positioned between the upper and lower portions of the processing chamber 10. As a result, the lower shower plate 41D partitions the interior of the processing chamber 10 into an upper space 12, where the shower head 30 is provided, and a lower space 11, where the stage 20 is provided.

A waveguide 53 is formed along the periphery of the support plate 42U located above the upper shower plate 42D, between the ceiling wall 10a and the support plate 42U. The waveguide 53 extends further vertically between the sidewall of the processing container 10 and the support plate 42U, reaching the upper surface of the periphery of the lower shower plate 41D. Between the upper shower plate 42D and the lower shower plate 41D, a ring-shaped dielectric radiation part 44 is disposed. The diameter of the outer surface of the radiation part 44 is equal to the diameter of the upper shower plate 42D. The radiation part 44 transmits the VHF power propagated through the waveguide 53 and radiates the VHF power into the plasma generation space 10u.

A plurality of second through-holes 42a that penetrate vertically through the upper electrode 42 are provided in the upper shower plate 42D. The reactive gas is supplied from the reactive gas source 63 via a gas supply line 64, which passes through a through-hole 65 in the ceiling wall 10a, an annular member 66 connecting the ceiling wall 10a and the support plate 42U, and a through-hole 67 in the support plate 42U, ultimately reaching the gas diffusion chamber 43 of the support plate 42U. The reactive gas is then discharged into the plasma generation space 10u from the plurality of second through-holes 42a of the upper shower plate 42D, which is coupled to the gas diffusion chamber 43.

On the opposite side of the plasma generation space 10u, separated by the lower shower plate 41D, a processing space 10s is formed between the lower shower plate 41D and the stage 20. The lower shower plate 41D is equipped with a plurality of first through-holes 41b that penetrate vertically through the lower electrode 41; the gas supplied to the plasma generation space 10u and the reactive species in the plasma diffuse through the multiple first through-holes 41b and are discharged into the processing space 10s.

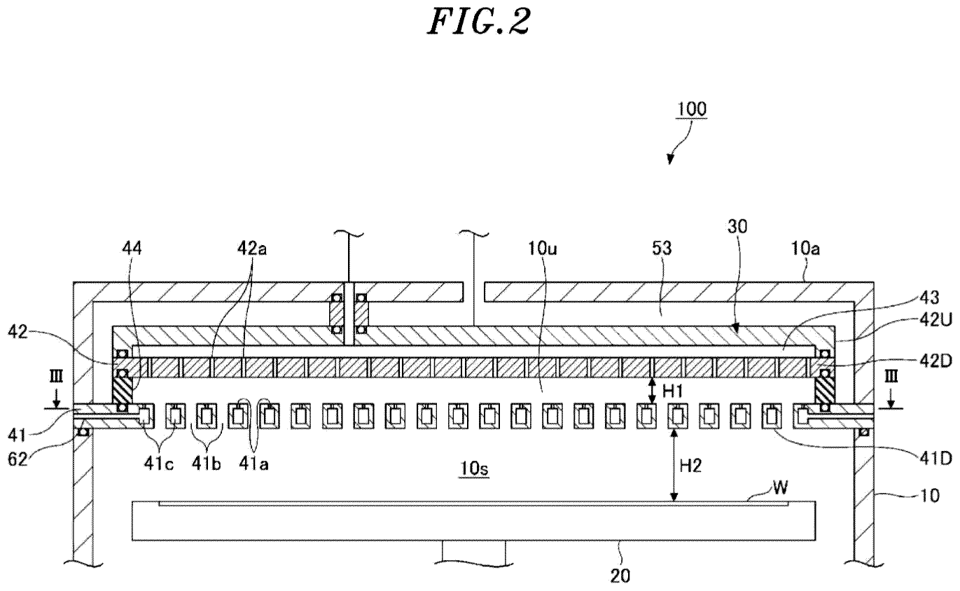

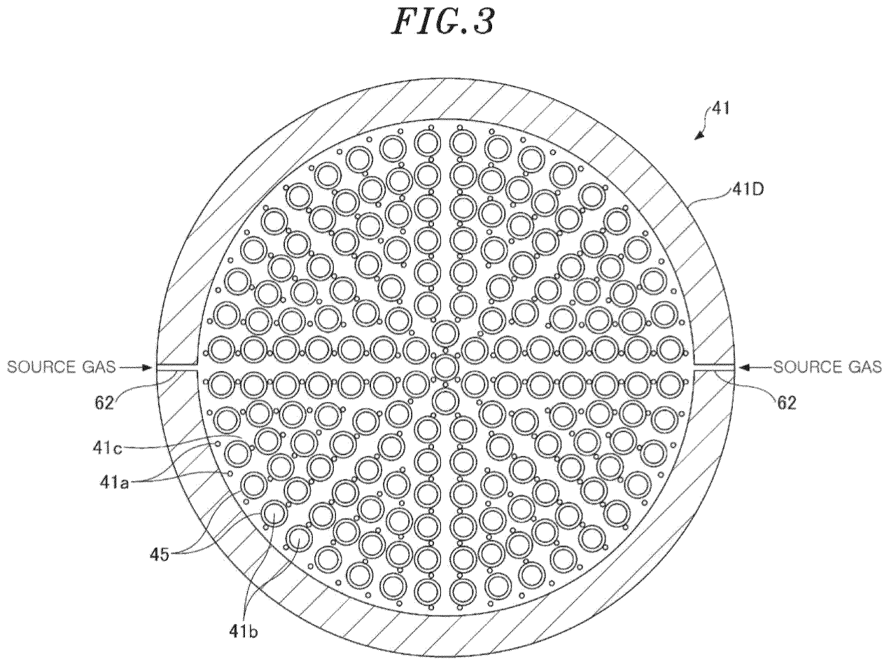

Referring further to FIGS. 2 and 3, the present disclosure will be described. FIG. 2 illustrates the showerhead structure of the plasma processing apparatus 100 and its surroundings according to the first embodiment. FIG. 3 is a cross-sectional view taken along line III-III of FIG. 2.

As shown in FIG. 3, the periphery of the lower shower plate 41D has two gas inlets 62 connected to the flow path 41c. The interior of the lower shower plate 41D is a space enclosed by the periphery of the lower shower plate 41D, where all areas, except for the plurality of first through-holes 41b, serve as the flow path 41c through which the source gas flows. The plurality of first through-holes 41b and the flow path 41c are separated by an annular partitioning wall 45. The partitioning wall 45 may, for example, be made of an aluminum alloy. As shown in FIG. 1, the source gas is supplied from the source gas supply 60, bifurcates via the gas supply line 61, and is introduced into the flow path 41c through the gas inlets 62.

The lower shower plate 41D is built on a shower plate structure that discharges source gas upward, opposite the direction directed from the plasma generation space 10u toward the processing space 10s, and supplies the source gas to the plasma generation space 10u. A plurality of gas holes 41a are provided in the lower shower plate 41D. The plurality of gas holes 41a are located above the flow path 41c of the lower electrode 41 and communicate with the flow path 41c. The plurality of gas holes 41a are open upward toward the plasma generation space 10u, discharging the source gas in an upward direction. In other words, the plurality of gas holes 41a are open on the opposite surface of a surface facing the lower shower plate 41D (surface of the plasma generation space 10u) and do not open toward the processing space 10s. Therefore, the source gas is configured to pass through the plasma generation space 10u before being supplied to the processing space 10s. This configuration allows the source gas to be introduced into the processing space 10s via the plurality of first through-holes 41b and subsequently adsorbed onto the substrate W.

For example, in the case of film formation via ALD, the source gas is first supplied from the lower shower plate 41D, being adsorbed onto the substrate W. At this time, VHF power is not supplied. Therefore, the source gas is supplied into the plasma generation space 10u through the plurality of gas holes 41a and is introduced into the processing space 10s from the plurality of first through-holes 41b without being turned into plasma. This operation enables the source gas to be chemically adsorbed onto the surface of the substrate W.

After the source gas is adsorbed onto the substrate W, a reactive gas is supplied into the plasma generation space 10u from a plurality of second through-holes 42a of the upper shower plate 42D. The reactive gas includes ammonia (NH₃) gas. At this time, VHF power is supplied to the plasma generation space 10u via the radiation part 44, causing the reactive gas to turn into plasma within the plasma generation space 10u. The reactive gas and the reactive species in the plasma are introduced into the processing space 10s through the plurality of first through-holes 41b. As a result, the source gas adsorbed onto the substrate W reacts with the reactive gas. When the reactive gas is NH₃ gas or N₂ gas, the silicon-containing gas undergoes nitridation; due to the NHₓ radicals generated from the decomposition of NH₃ molecules, the surface of the substrate W undergoes nitridation, forming a nitride film on the substrate W.

The source gas is an example of a first processing gas. The first processing gas includes a silicon-containing gas as the source gas. The silicon-containing gas may be silane SiH₄ gas, dichlorosilane (SiH₂Cl₂: DCS) gas, or trisilylamine (Si₃H₉N: TSA) gas. In addition to the source gas, the first processing gas may also include a plasma excitation gas. The plasma excitation gas may be an inert gas such as argon Ar gas.

The reactive gas is an example of a second processing gas. The second processing gas includes a nitrogen-containing gas as the reactive gas. The reactive gas may be NH₃ gas or N₂ gas. In addition to the reactive gas, the second processing gas may also include a plasma excitation gas. The plasma excitation gas may be an inert gas such as Ar gas.

As shown in FIG. 2, the distance H1 (gap of the plasma generation space 10u) between the upper electrode 42 and the lower electrode 41 is 2 mm. The distance H2 (gap of the processing space 10s) between the lower electrode 41 and the stage 20 is within the range from 10 mm to 20 mm.

As described above, the present embodiment provides a remote-type plasma processing apparatus 100 that excites plasma using VHF power supplied between the upper electrode 42 and the lower electrode 41. In the plasma processing apparatus 100, the openings of the plurality of gas holes 41a in the lower shower plate 41D are formed to face upward. As a result, even if the gap in the processing space 10s is narrowed down to approximately 10 millimeters to 20 millimeters compared to conventional structures, the pattern of the gas holes 41a is less likely to transfer onto the film, thereby promoting uniformity in substrate processing.

To suppress the deactivation of reactive species within the base layer, it is preferable that the gap in the processing space 10s be small. If the openings of the plurality of gas holes 41a in the lower shower plate 41D face downward as in the conventional structures, the film on the substrate W becomes thicker below the openings of the plurality of gas holes 41a, and the pattern of the plurality of gas holes 41a is transferred onto the film, which makes substrate processing carried out in a non-uniform manner.

On the other hand, if the gap H2 of the processing space 10s is increased to avoid the transfer of the pattern of the plurality of gas holes 41a, during film formation using ALD, for example, it becomes necessary to perform gas replacement at high speed; however, performing gas replacement at high speed increases the processing time of the substrate W, which in turn decreases the production efficiency of semiconductors.

Compared to the description above, in the plasma processing apparatus 100 of the present disclosure, the source gas is supplied upward into the plasma generation space 10u from the plurality of gas holes 41a of the lower shower plate 41D and is then supplied to the processing space 10s through the plurality of first through-holes 41b from the plasma generation space 10u. At this time, the flow rate of the source gas supplied to the processing space 10s from the plurality of first through-holes 41b is slower than the flow rate of the source gas when the openings of the plurality of gas holes 41a are directed downward. Therefore, it becomes difficult for the pattern of the plurality of gas holes 41a to transfer to the film formed on the substrate W. With this configuration, the plasma processing apparatus 100 of the present disclosure may reduce the gap H2 of the processing space 10s to a range from 10 mm to 20 mm. As a result, the deactivation of reactive species supplied to the surface of the substrate W is suppressed, and the plasma processing speed may be improved. Also, the transfer of the pattern of the plurality of gas holes 41a may be avoided, thereby improving the uniformity of substrate processing. Furthermore, since most of the charged particles in the plasma that enter the plurality of first through-holes 41b recombine on the inner surface of the first through-holes 41b, only a small portion is discharged into the processing space 10s. Therefore, a high-quality process free from damage by ion incidence on the substrate W may be performed. Also, since the gap H2 of the processing space 10s is small, the gas replacement time in the processing space 10s is shortened. Therefore, the time required for the ALD process is reduced, and the production efficiency of semiconductors is improved.

The diameter of the plurality of gas holes 41a of the lower electrode 41 is set to be smaller than the diameter of the plurality of first through-holes 41b. For example, the diameter of the gas holes 41a is within the range from 0.2 mm to 1 mm. The diameter of the first through-holes 41b is within the range from 4 mm to 40 mm. This configuration makes it difficult for gas to flow backward into the gas holes 41a, thereby suppressing the back diffusion of gas into the flow path 41c inside the lower electrode 41.

As described above, because the plurality of gas holes 41a are small, the flow speed is high near the gas holes 41a. Therefore, if the plurality of gas holes 41a are opened toward the substrate side, the high-speed source gas is sprayed onto the surface of substrate W before it is sufficiently mixed with the plasma excitation gas. Therefore, the pattern of the plurality of gas holes 41a is likely to be transferred onto the film formed on substrate W, leading to non-uniform substrate processing. On the other hand, in the plasma processing apparatus 100 of the present disclosure, the source gas is mixed and diluted in the plasma generation space 10u with the plasma excitation gas supplied from the plurality of gas holes 41a and/or the plurality of second through-holes 42a. The plasma excitation gas mixed in the plasma generation space 10u, source gas, and the reactive species generated in the plasma are discharged at a low flow speed from the first through-holes 41b of the lower electrode 41 into the processing space 10s and supplied to the surface of substrate W. Therefore, the pattern of the plurality of gas holes 41a is less likely to be transferred onto the film.

Also, the diameter of the plurality of second through-holes 42a of the upper electrode 42 is smaller than the diameter of the plurality of first through-holes 41b of the lower electrode 41. This configuration suppresses the back-diffusion of the source gas into the second through-holes 42a, thereby preventing film formation within the second through-holes 42a or the gas diffusion chamber 43.

Also, while the source gas is supplied to the plasma generation space 10u, a dilution gas such as Ar gas may be flowed through the plurality of second through-holes 42a to suppress the ingress of the source gas into the second through-holes 42a. In this case, the dilution gas functions as a suppression gas to inhibit entrance of the source gas. The dilution gas functioning as a suppression gas may include at least one of Ar gas, N₂ gas, H₂ gas, or O₂ gas.

Furthermore, while the reactive gas is supplied to the plasma generation space 10u, a dilution gas such as Ar gas may be flowed through the plurality of gas holes 41a to facilitate plasma ignition and suppress the ingress of the reactive gas into the plurality of gas holes 41a. In this case, the dilution gas functions both as a suppression gas to inhibit the ingress of the reactive gas into the gas holes 41a and as a plasma excitation gas. The dilution gas functioning as a suppression gas may include at least one of Ar gas, N₂ gas, H₂ gas, or O₂ gas.

The plurality of gas holes 41a, the plurality of first through-holes 41b, and the plurality of second through-holes 42a are arranged such that they do not overlap in a plan view. This arrangement makes it difficult for the gas supplied upward from the plurality of gas holes 41a and the gas supplied downward from the plurality of second through-holes 42a to enter each other's respective holes. Also, this configuration may reduce the flow speed of the gas supplied to the processing space 10s from the plurality of first through-holes 41b.

The controller 80 processes computer-executable instructions to perform various processes, such as film formation via ALD, on the plasma processing apparatus 100. The controller 80 may be configured to control each component of the plasma processing apparatus 100 to execute various processes. In one embodiment, all or part of the controller 80 may be included within the plasma processing apparatus 100. The controller 80 may include a processor, a memory, and a communication interface. The controller 80 may, for example, be implemented by a computer. The processor may be configured to read programs from the memory and execute various control operations by executing the read programs. These programs may be pre-stored in the memory or acquired as needed through a medium. The acquired programs may be stored in the memory and executed after being read from the memory by the processor. The medium may include various storage media readable by the computer or communication lines connected to the communication interface. The processor may be a Central Processing Unit (CPU). The memory may include a Random Access Memory (RAM), a Read Only Memory (ROM), a Hard Disk Drive (HDD), a Solid State Drive (SSD), or a combination thereof. The communication interface may communicate with the plasma processing apparatus 100 via communication lines such as a Local Area Network (LAN).

### An Example of Film Forming Method

The plasma processing apparatus 100 of the present disclosure may be applied to processes such as Plasma-Enhanced Atomic Layer Deposition (PE-ALD), Plasma-Enhanced Chemical Vapor Deposition (PE-CVD), and Plasma-Enhanced Atomic Layer Etching (PE-ALE). For example, in the SiN film formation process using PE-ALD, DCS (dichlorosilane) gas is used as a source gas, and NH₃ gas is used as a reactant gas. Also, for example, Ar gas is used as a dilution gas (plasma excitation gas) and as a purge gas.

An ALD cycle consists of four steps: an adsorption step, a first purge step, a reaction step, and a second purge step.

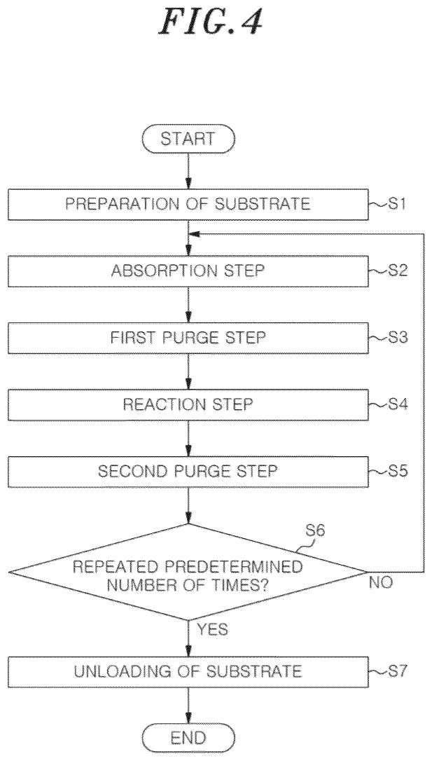

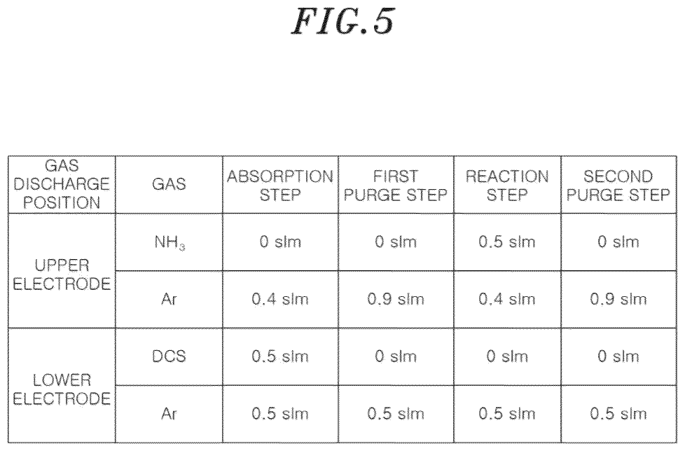

A film forming method according to one embodiment will be described with reference to FIGS. 4 and 5. FIG. 4 illustrates an example of a film forming method using ALD according to one embodiment. FIG. 5 illustrates an example of a gas used in the film forming method of FIG. 4.

The film forming method using ALD according to the present disclosure is controlled by the controller 80 and executed by the plasma processing apparatus 100. Once the present processing begins, the substrate W is placed on the stage 20 and prepared in the S1 step.

Next, in the S2 step, an adsorption step is executed. During the adsorption step, DCS gas is supplied upward into the plasma generation space 10u from the plurality of gas holes 41a of the lower electrode 41. Also, Ar gas is supplied into the plasma generation space 10u from the plurality of second through-holes 42a of the upper electrode 42 and the plurality of gas holes 41a. For example, as shown in FIG. 5, during the adsorption step, 0.4 slm of Ar gas is supplied from the upper electrode 42, while 0.5 slm of DCS gas and Ar gas are supplied from the lower electrode 41.

By doing so, DCS gas and Ar gas are supplied to the plasma generation space 10u while preventing the DCS gas from entering the plurality of second through-holes 42a; the DCS gas and Ar gas are then introduced into the processing space 10s through the plurality of first through-holes 41b of the lower electrode 41. The DCS molecules react with the H group on the surface of the substrate W and are chemically absorbed on the surface.

Next, in the S3 step, the first purge step is executed. In the first purge step, Ar gas is supplied as an example of the purge gas through the plurality of second through-holes 42a and the plurality of gas holes 41a, which replaces the interior of the processing chamber 10 with Ar gas and purges DCS gas from the processing chamber 10. For instance, as shown in FIG. 5, in the first purge step, 0.9 slm of Ar gas is supplied from the upper electrode 42, and 0.5 slm of Ar gas is supplied from the lower electrode 41. During the first purge step, Ar gas is discharged from both the upper electrode 42 and the lower electrode 41, replacing the processing space 10s with Ar gas.

Next, in the S4 step, the reaction step is executed. In the reaction step, NH₃ gas and Ar gas are supplied into the plasma generation space 10u through the plurality of second through-holes 42a of the upper electrode 42. Also, Ar gas is supplied into the plasma generation space 10u through the plurality of gas holes 41a of the lower electrode 41. Furthermore, VHF power is supplied to the plasma generation space 10u. For example, as shown in FIG. 5, during the reaction step, 0.5 slm of NH₃ gas and 0.4 slm of Ar gas are supplied from the upper electrode 42, and 0.5 slm of Ar gas is supplied from the lower electrode 41.

The reaction step prevents NH₃ gas from entering the plurality of gas holes 41a, generates plasma of NH₃ gas and Ar gas, and supplies the reactive species in the plasma to the processing space 10s through the plurality of first through-holes 41b of the lower electrode 41. During the reaction step, NH₃ gas is discharged from the plurality of second through-holes 42a provided in the upper electrode 42, and plasma is excited using, for example, 1 kW of VHF power. The NHx radicals generated by the decomposition of NH₃ molecules remove Cl atoms from the surface of substrate W and simultaneously nitride the surface, forming stable SiN bonds. As a result, an SiN film is formed on substrate W.

Next, in the S5 step, the second purge step is performed. In the second purge step, an example of a purge gas, such as Ar gas, is supplied through the plurality of second through-holes 42a and plurality of gas holes 41a to replace the interior of the processing container 10 with Ar gas, thereby purging NH₃ gas from the processing chamber 10. For example, as shown in FIG. 5, during the second purge step, 0.9 slm of Ar gas is supplied from the upper electrode 42, and 0.5 slm of Ar gas is supplied from the lower electrode 41. In the second purge step, Ar gas is discharged from both the upper electrode 42 and the lower electrode 41, and the processing space 10s is replaced with Ar gas.

Next, in the S6 step, it is determined whether the set number of repetitions has been completed. Until the set number of repetitions is reached, processing of S2 to S5 steps are repeated. In the S6 step, if it is determined that the set number of repetitions has been completed, in the S7 step, the substrate W is unloaded, and the present processing is terminated.

When the set number of repetitions is configured to be several tens to several hundred cycles, the repetition of ALD cycles in the S2 to S5 steps forms a thin SiN film with a thickness of several nanometers to several tens of nanometers.

### Second Embodiment

### Plasma Processing Apparatus

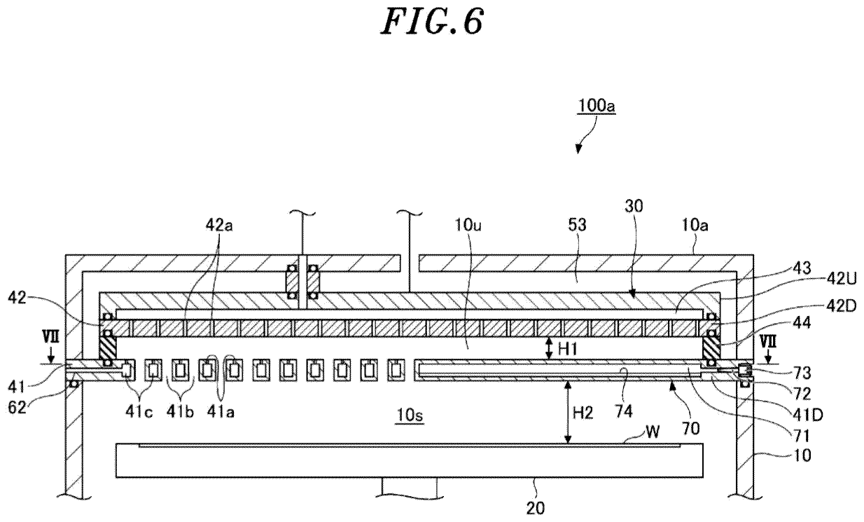

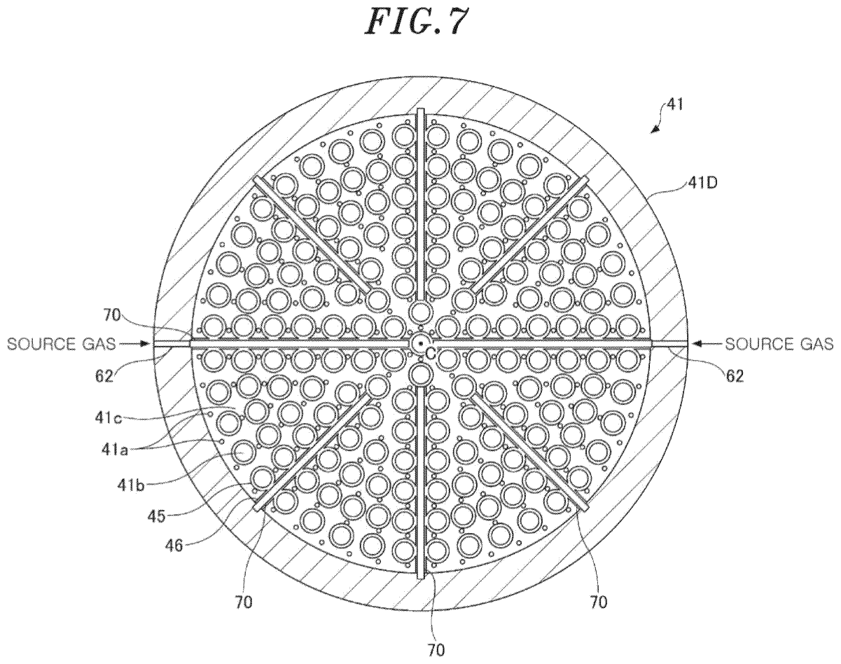

Next, the configuration of the plasma processing apparatus 100a according to a second embodiment will be described with reference to FIGS. 6 and 7. FIG. 6 is a cross-sectional schematic diagram showing an example of the plasma processing apparatus 100a according to the second embodiment. FIG. 7 is a cross-sectional view taken along line VII-VII of FIG. 6.

To suppress the deactivation of reactive species passing through the plurality of first through-holes 41b provided in the lower electrode 41, it is preferable that the path length of the first through-holes 41b be short, namely, that the lower electrode 41 be thin. On the other hand, the lower electrode 41 is heated due to the inflow of charged particles from the plasma to the surface of the lower electrode 41 and introduction of radiant heat from the stage 20. Also, when plasma is generated in the plasma generation space 10u, heat from the plasma flows into the lower electrode 41.

Since the periphery of the lower electrode 41 is connected to the sidewall of the processing chamber 10, the heat flowing into the lower electrode 41 is transferred from the periphery of the lower electrode 41 to the sidewall of the processing chamber 10. Therefore, the temperature is higher at the central portion of the lower electrode 41 and lower at the periphery, resulting in a temperature distribution within the lower electrode 41. Due to this temperature distribution, thermal expansion causes stress on the lower electrode 41, which may make the lower electrode 41 bent or damaged. If the lower electrode 41 is made thinner, the thermal resistance increases, exacerbating the deformation of the lower electrode 41. As a result, the gap H1 between the upper electrode 42 and the lower electrode 41 or the gap H2 between the lower electrode 41 and the stage 20 may deviate from the design values, making it impossible to perform a normal process.

To prevent the occurrence of a temperature distribution within the lower electrode 41, the lower electrode 41 may be made thicker. However, if the lower electrode 41 is made thicker, as described above, the path length of the first through-holes 41b becomes longer; therefore, reactive species generated in the plasma generation space 10u collide and recombine with the walls of the through-holes while passing through the first through-holes 41b of the lower electrode 41, becoming more likely to be deactivated. When the path length of the first through-holes 41b increases, reactive species such as radicals exponentially decrease.

Therefore, in the plasma processing apparatus 100a according to the second embodiment, a heat pipe 70 is embedded in the lower electrode 41 to equalize the temperature of the lower electrode 41, making it difficult for a temperature distribution to occur within the lower electrode 41, even if the thickness of the lower electrode 41 is thin.

The difference between the plasma processing apparatus 100a of the second embodiment and the plasma processing apparatus 100 of the first embodiment lies solely in the inclusion of the heat pipe 70 in the lower electrode 41, while the other configurations remain the same. Accordingly, only the configuration of the lower electrode 41 will be described below, but the description of other configurations will be omitted.

Referring to FIG. 7, which is a cross-sectional view of FIG. 6 taken along line VII-VII, eight heat pipes 70 are radially provided within the lower shower plate 41D. The first through-holes 41b are disposed at positions that do not interfere with the heat pipes 70. The lower shower plate 41D has a disk shape, and the plurality of heat pipes 70 are in the form of straight line. Each heat pipe 70 is disposed in the radial direction so that its end is directed toward the center C of the lower shower plate 41D. In other words, the longitudinal direction of each heat pipe 70 is oriented along the radial direction.

The interiors of the plurality of first through-holes 41b and the flow path 41c are separated by an annular partitioning wall 45. The interiors of the plurality of heat pipes 70 and the flow path 41c are separated by a rectangular partitioning wall 46. The partitioning walls 45 and 46 may, for example, be formed of an aluminum alloy. A capillary structure, or wick, may be formed inside the heat pipes 70.

As shown in FIG. 6, the interior of the heat pipe 70 contains a working fluid 74. The working fluid 74 consists of liquids such as pure water, alcohol, or freon. The lower shower plate 41D is heated due to the inflow of charged particles from the plasma to the surface and the inflow of radiant heat from the stage 20. The working fluid 74 inside the heat pipe 70 absorbs latent heat of evaporation and evaporates, causing a localized increase in pressure inside the heat pipe 70. The vapor rapidly moves to the periphery of the lower electrode 41, where the temperature and pressure are lower. At the periphery of the lower electrode 41, the vapor condenses, releasing latent heat of condensation. As described above, by introducing the heat pipe 70 mechanism, the thermal conductivity in the radial direction of the lower shower plate 41D may be drastically increased. As a result, the temperature of the lower electrode 41 may be equalized, and deformation or damage, such as bending of the lower electrode 41, may be suppressed.

### Method for Manufacturing Lower Shower Plate

Next, a method for manufacturing a lower electrode 41 equipped with a heat pipe 70 mechanism will be described. First, the lower shower plate 41D with an internal structure shown in FIG. 6 is constructed through diffusion bonding. For example, the internal flow path 41c of the lower shower plate 41D or the space for the heat pipe is formed, upper and lower parts divided into upper and lower components of the lower shower plate 41D are fabricated by machining, and the upper and lower components are then diffusion-bonded together to form an integrated structure.

Next, an appropriate amount of working fluid 74 is injected into the space 71 of the heat pipe 70 through the inlet of the working fluid. Subsequently, the lower shower plate 41D is cooled down to a temperature at which the working fluid 74 freezes. At this time, a vacuum evacuation device (not shown) is connected to the inlet of the working fluid 74, the space 71 of the heat pipe 70 is evacuated to create a vacuum, and the heat pipe 70 is sealed with a rubber stopper 72 while the vacuum state is maintained. Afterward, the vacuum evacuation device is detached. To ensure airtightness, the heat pipe 70 is additionally sealed using screws 73 and adhesive. Through the process above, the working fluid 74 may be encapsulated within the heat pipe 70 without introducing any impurities except for the working fluid 74. As a result, the lower shower plate 41D embedding the heat pipe 70 may be manufactured. However, the method for manufacturing the lower shower plate 41D is not limited to the process described above.

### Modified Example

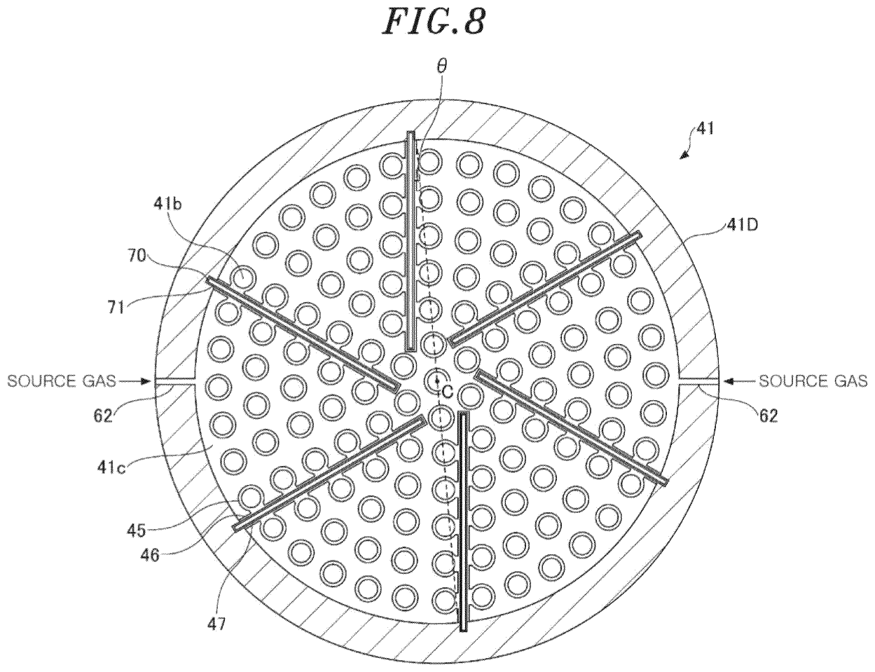

FIG. 8 illustrates a modified example of a lower shower plate 41D (heat pipe 70) of a plasma processing apparatus 100a according to the second embodiment. FIG. 8 is another example of a cross-sectional view taken along VII-VII line of FIG. 6. Also, the lower electrode 41 of FIG. 8 omits the illustration of a plurality of gas holes 41a.

The gas discharged into the processing space 10s from the first through-holes 41b flows radially across the substrate W and is exhausted from the periphery of the stage 20. If the first through-holes 41b are disposed in a straight line along the radial direction, the gas flow in that direction becomes greater than in other areas, potentially causing a bias in the circumferential direction of the gas flow. To avoid the directional bias, it is preferable to dispose the first through-holes 41b in such a way that they are not disposed in a straight line along the radial direction. The first through-holes 41b are disposed to avoid interference with the heat pipes 70. Each of the plurality of heat pipes 70 is disposed to have an inclination relative to the radial direction, so that their ends do not point toward the center C of the lower electrode 41. For example, as shown in FIG. 8, the heat pipes 70 in a straight line form are disposed at an angle θ relative to a line passing through the center C in the radial direction. This configuration helps mitigate deviations in the circumferential gas flow. Even when curved heat pipes are disposed, the same effect may be achieved.

In the plasma processing apparatus 100a according to the second embodiment, the introduction of the heat pipe 70 mechanism into the lower shower plate 41D realizes a lower electrode 41 that is thin but exhibits excellent thermal conductivity. As a result, even when high-power high-frequency power is supplied to the shower head 30, issues such as bending or damaging of the lower shower plate 41D do not occur, and deactivation of reactive species passing through the first through-holes 41b of the lower shower plate 41D is suppressed. This allows a large number of active species to be supplied to the processing space 10s. Furthermore, the plasma processing time is reduced, leading to improved semiconductor production efficiency.

When a plurality of gas holes 41a are provided above the flow path 41c of the lower electrode 41, the source gas is discharged into the plasma generation space 10u between the lower electrode 41 and the upper electrode 42. The discharged source gas is introduced into the processing space 10s through the plurality of first through-holes 41b of the lower electrode 41. Subsequently, purging gas is supplied to purge the source gas from the plasma generation space 10u. If the purging is insufficient, residual source gas in the plasma generation space 10u may be decomposed by plasma, making it easier for reaction by-products to accumulate on the surfaces of the lower electrode 41 and the upper electrode 42. To suppress the deposition of reaction by-products, the temperatures of the lower electrode 41 and the upper electrode 42 should be set to the temperature high enough to facilitate the volatilization of the reaction by-products. For example, in the ALD process for silicon nitride (SiN film) using DCS gas and NH₃ gas, compounds of Si, Cl, N, and H are generated as reaction by-products. To prevent the adhesion of reaction by-products, the temperature should be set to, for example, 150° C. or higher.

Meanwhile, if the lower electrode 41 is heated to a high temperature, the yield strength of the material of the lower electrode 41 may decrease, increasing the likelihood of plastic deformation due to thermal stress caused by the inflow of radiant heat from the stage 20 or heat from the plasma. To make it difficult for plastic deformation to occur even when the lower electrode 41 is heated to a high temperature, it is effective to reduce thermal stress, namely, to uniformly heat the lower electrode 41. Therefore, for a lower electrode 41 that has a plurality of gas holes 41a provided above the flow path 41c of the lower electrode 41, it is effective to introduce a heat pipe 70 structure.

Furthermore, each of the plurality of heat pipes 70 may be inserted into a space 71 separated from the flow path 41c of the lower electrode 41 by a partitioning wall 46 formed of an aluminum alloy. As shown in FIG. 8, the heat pipe 70, formed of copper and containing a working fluid, is inserted into the space 71 within the partitioning wall 46 through an opening (not shown) located at the periphery of the lower electrode 41. The mechanism above allows disposition of rectangular heat pipes 70 with a dual-structure configuration comprising the aluminum alloy partitioning wall 46 and the copper partitioning wall 47. Accordingly, since the heat pipe 70 may be inserted as a finished product into the space 71, the installation of screws 73 or rubber stoppers 72, which were used in the manufacturing method described above, may no longer be necessary. Also, operations such as sealing the working fluid are also rendered unnecessary, thereby improving the efficiency of installing the heat pipes 70.

As described above, according to the plasma processing apparatus of the present embodiment, the uniformity of substrate processing may be achieved.

The plasma processing apparatus according to the present embodiments should be considered illustrative in all aspects and not restrictive. The embodiments may be modified and improved in various forms without departing from the scope and spirit of the appended claims. The elements described in the plurality of embodiments may adopt alternative configurations or may be combined with each other as long as they do not contradict each other.

The lower electrode of the present disclosure may be applied to any type of plasma processing apparatus, including Atomic Layer Deposition (ALD), Capacitively Coupled Plasma (CCP), Inductively Coupled Plasma (ICP), Radial Line Slot Antenna (RLSA), Electron Cyclotron Resonance Plasma (ECR), and Helicon Wave Plasma (HWP) devices.

Also, the plasma processing apparatus of the present disclosure may be applied to a single-wafer device that processes substrates one at a time, as well as batch or semi-batch devices that process a plurality of substrates simultaneously.

This application claims priority to Japanese Patent Application No. 2022-144117, filed with the Japan Patent Office on Sep. 9, 2022, the entire contents of which are incorporated herein by reference.

1. A plasma processing apparatus comprising:
a processing chamber that has a stage on which a substrate is placed;
a first electrode to which high-frequency power for plasma generation is supplied;
a second electrode that faces the first electrode and is configured to form a plasma generation space between the first electrode and the second electrode; and
a radiation part that is formed of a dielectric and is configured to radiate the high-frequency power into the plasma generation space from a waveguide formed along an outer periphery of the first electrode,
wherein the second electrode is configured to form a processing space between the stage and the second electrode, and has a structure causing a first processing gas to flow in a direction opposite to a direction from the plasma generation space toward the processing space, to supply the first processing gas to the plasma generation space.

2. The apparatus of claim 1, wherein the second electrode includes:
a flow path formed inside the second electrode; and
a plurality of gas holes that communicate with the flow path and are open toward the plasma generation space,
wherein the structure includes a showerhead structure configured to supply the first process gas from the flow path to the plurality of gas holes.

3. The apparatus of claim 2, wherein the second electrode has a plurality of first through-holes penetrating the second electrode,
wherein the first processing gas supplied to the plasma generation space is introduced into the processing space through the plurality of first through-holes to process the substrate.

4. The apparatus of claim 3, wherein a diameter of the plurality of gas holes is smaller than a diameter of the plurality of first through-holes.

5. The apparatus of claim 4, wherein the first electrode has a plurality of second through-holes penetrating the first electrode, and
the plurality of gas holes, the plurality of first through-holes, and the plurality of second through-holes are arranged such that they do not overlap in a plan view.

6. The apparatus of claim 5, wherein the first electrode has a showerhead structure causing a second processing gas to flow through the plurality of second through-holes, to supply the second processing gas to the plasma generation space.

7. The apparatus of claim 6, wherein the second electrode introduces reactive species in plasma of the second processing gas supplied to the plasma generation space by high-frequency power radiated from the radiation part into the processing space through the plurality of first through-holes, to perform plasma processing on the substrate.

8. The apparatus of claim 1, wherein a gap between the second electrode and the stage is within a range of 10 mm to 20 mm.

9. The apparatus of claim 1, wherein the high-frequency power is a VHF power.

10. The apparatus of claim 6, wherein the first processing gas includes a silicon-containing gas as a source gas,
the second processing gas includes a nitrogen-containing gas as a reactive gas, and
the plasma processing apparatus forms a silicon nitride film on the substrate by processing the substrate using the first process gas and the second process gas.

11. The apparatus of claim 10, wherein the silicon-containing gas is silane (SiH₄) gas, dichlorosilane (SiH₂Cl₂: DCS) gas, or trisilylamine (Si₃H₉N: TSA) gas, and
the nitrogen-containing gas is NH₃ gas or N₂ gas.

12. The apparatus of claim 10, wherein the plasma processing apparatus includes a controller,
wherein the controller is configured to control:
(a) a step of supplying the first process gas from the plurality of gas holes provided in the second electrode to adsorb a silicon-containing gas onto the substrate;
(b) a step of supplying a purge gas from the plurality of second through-holes penetrating the first electrode and the plurality of gas holes provided in the second electrode to purge the first process gas from the processing chamber;
(c) a step of supplying the second process gas from the plurality of second through-holes penetrating the first electrode to perform a plasma-process on the substrate using reactive species in the plasma of the second process gas;
(d) a step of supplying a purge gas from the plurality of second through-holes penetrating the first electrode and the plurality of gas holes provided in the second electrode to purge the second process gas from the processing chamber; and
(e) repeating the steps (a) to (d) in that order for a predetermined number of cycles.

13. The apparatus of claim 12, wherein:
in the step (a), a suppression gas is supplied from the plurality of second through-holes penetrating the first electrode to suppress ingress of the first process gas, and
in the step (c), a suppression gas is supplied from the plurality of gas holes provided in the second electrode to suppress ingress of the second process gas.

14. The apparatus of claim 13, wherein the suppression gas is Ar gas, N₂ gas, or O₂ gas.

15. The apparatus of claim 1, wherein the second electrode has a plurality of heat pipes inside the second electrode.

16. The apparatus of claim 15, wherein the second electrode has a disk shape, and
each of the plurality of heat pipes is disposed in a radial direction such that its end is directed toward a center of the second electrode.

17. The apparatus of claim 15, wherein the second electrode has a disk shape, and
each of the plurality of heat pipes is disposed in a radial direction such that its end is not directed toward a center of the second electrode.

18. The apparatus of claim 15, wherein each of the plurality of heat pipes is separated from a flow path in the second electrode by a partitioning wall.

19. The apparatus of claim 15, wherein each of the plurality of heat pipes is inserted into a space separated from a flow path in the second electrode by a partitioning wall.
